(19) United States
(12) Patent Application Publication
(10) Pub. No.: US 2015/0301081 A1
(43) Pub. Date: Oct. 22, 2015

(54) ELECTRICAL CONTACT MEMBER AND INSPECTION CONNECTION DEVICE

(71) Applicant: KABUSHIKI KAISHA KOBE SEIKO SHO (KOBE STEEL, LTD.), Kobe-shi, Hyogo (JP)

(72) Inventors: Takayuki HIRANO, Kobe-shi (JP); Nobuyuki KAWAKAMI, Kobe-shi (JP)

(21) Appl. No.: 14/440,639

(22) PCT Filed: Dec. 12, 2013
(86) PCT No.: PCT/JP13/83400

§ 371 Date: May 5, 2015

(30) Foreign Application Priority Data
Dec. 14, 2012 (JP) 2012-274117

(51) Int. Cl. G01R 1/067; G01R 1/04; H01R 13/03; G01R 31/28

(52) U.S. Cl. CPC G01R 1/06755; G01R 31/2886; G01R 1/0416; H01R 13/03

(57) ABSTRACT

An electrical contact member repeatedly contacts a subject. The surface of the electrical contact member that contacts a subject is configured from a metallic-element-containing carbon coating film containing a metallic element. The surface roughness of the metallic-element-containing carbon coating film formed at an inclined surface that is at 45° with respect to the axial line of the electrical contact member is no greater than a certain value. As a result, it is possible to achieve low adhesiveness to the subject, an increase in contact resistance is stably suppressed over the long term, and it is possible to maintain a stable electrical contact.

### TECHNICAL FIELD

The present invention relates to an electrical contact member and an inspection connection device including the electrical contact member.

### BACKGROUND ART

When electric properties of an electronic component such as an integrated circuit (IC), a large scale integration (LSI), and a light emitting diode (LED), i.e., an electronic component including a semiconductor element, are inspected, an electrical contact member (contact terminal) used in an inspection connection device is brought into contact with an electrode of the semiconductor element. The electrical contact member is required to not only have good conductivity (a low contact resistance value), but also have good durability to the extent that it is not worn out or damaged even after repeated contacts with the electrode as a subject.

Although the contact resistance value of the electrical contact member is typically set to 100 mΩ or less, it may increase to several hundred milliohms to several ohms through repeated inspections with a subject. To cope with this, the electrical contact member has been regularly cleaned or changed. This however greatly reduces reliability of an inspection step and an availability factor of an inspection connection device. Hence, there is now developed an electrical contact member having a contact resistance value that is not increased even after long-term repeated use. In particular, when the electrode as the subject is composed of solder or tin (Sn) plating, the electrode surface is scraped through contact with the electrical contact member because solder or tin is soft, and chips of the electrode surface tend to adhere to the tip of the electrical contact member. The adhered solder or tin is readily oxidized, leading to an increase in contact resistance of the electrical contact member. In addition, the electrical contact member becomes insufficiently in contact with the objective electrode due to physical obstruction by the adhered tin or solder, due to which contact resistance increases. Consequently, it is difficult to stably maintain the contact resistance value of the electrical contact member at a low level.

Examples of a method of stabilizing the contact resistance value of the electrical contact member include those described in PTL 1 and PTL 2. PTL 1 discloses an amorphous hard coating mainly composed of carbon and hydrogen. The hard coating contains not only carbon and hydrogen, but also at least one impurity element selected from a group consisting of V, Cr, Zr, Nb, Hf, Ta, Au, Pt, and Ag in a range from 0.001 to 40 atom %. This allows the hard coating to have good wear resistance and high conductivity, and have small film stress, leading to good sliding properties. It is described that the hard coating is preferably usable for a sliding section that must be subjected to electrical contact.

PTL 2 discloses a probe including tungsten or rhenium tungsten. The probe has a diamond like carbon (DLC) film on at least a tip of a contact section on its leading side, the DLC film containing, in a range from 1 to 50 mass %, at least one metal among tungsten, molybdenum, gold, silver, nickel, cobalt, chromium, palladium, rhodium, iron, indium, tin, lead, aluminum, tantalum, titanium, copper, manganese, platinum, bismuth, zinc, and cadmium. It is described that even if the probe having such a configuration repeatedly comes into contact with an aluminum electrode, aluminum scraps are less likely to adhere to the probe, and low contact resistance can be stably maintained without frequent cleaning.

In the technique of each of the PTLs 1 and 2, a metallic element such as tungsten is contained into a carbon coating such as DLC, thereby the high conductivity due to the added metallic element and low adhesion of the subject (an objective material such as tin alloy) to the electrical contact member due to the metallic-element-containing carbon coating are effectively exhibited together.

On the other hand, PTLs 3 and 4 describe that high smoothness (low roughness) of the surface of the electrical contact member that is to come into contact with the electrode, and high smoothness (low roughness) of the metallic-element-containing carbon coating provided on an uppermost surface are effective in reducing Sn adhesion.

Specifically, PTL 3 discloses a contact terminal that is to come into contact with an electrode of a semiconductor device. The maximum height Ry in the surface roughness of the portion, which is to come into contact with the electrode, of the contact terminal is controlled to be 10 μm or less. It is described that such a maximum height Ry can be achieved through mechanical chemical polishing or dry polishing of the surface of the substrate of the contact terminal. Furthermore, a carbon coating containing a metallic element is provided on the uppermost surface. However, the surface roughness of the carbon coating is regarded to reflect the shape of the substrate surface, and no investigation is made on influence on Sn adhesion of the surface texture of the carbon coating itself.

PTL 4 discloses an improvement of the technology of PTL 3. Specifically, PTL 4 discloses an invention achieved based on the following finding: When a coating is formed on a substrate, the surface texture of the coating affects tin adhesion, and tin adhesion is disadvantageous depending on coating formation conditions even in a region where Ry of 10 μm or less is satisfied as in PTL 3. While influence of a microscopic surface texture of the coating on tin adhesion resistance has not been investigated, PTL 4 focuses on such influence, and describes that tin adhesion resistance is improved by controlling a parameter of the microscopic surface texture of the coating. Specifically, PTL 4 discloses a contact probe pin for a semiconductor inspection apparatus, in which an amorphous carbon-based conductive coating provided on the surface of the conductive substrate has an outer surface of which the surface roughness (Ra) is 6.0 nm or less, the root square slope (RAq) is 0.28 or less, and the average (R) of tip curvature radii of convex portions in the surface texture is 180 nm or more.

### CITATION LIST

### Patent Literature

PTL 1: Japanese Patent No. 3336682.

PTL 2: Japanese Unexamined Patent Application Publication No. 2001-289874.

PTL 3: Japanese Unexamined Patent Application Publication No. 2007-24613.

PTL 4: Japanese Unexamined Patent Application Publication No. 2011-64497.

### SUMMARY OF INVENTION

### Technical Problem

The technology described in each of PTLs 1 to 4 will provide an electrical contact member that withstands repeated inspections under room temperature. However, since the electrical contact member is used in various environments, it may be used in an environment under high temperature, which is more severe than under room temperature. For example, when the electrical contact member is used in repeated inspections under high temperature of about 85° C., an electrode member such as a Sn electrode heated to high temperature comes into contact with the electrical contact member, which greatly increases adhesion rate of Sn to the electrical contact member, and disadvantageously leads to significant improvement in conductivity of the electrical contact member. However, the technology of each of PTLs 1 to 4 does not involve the investigation from such a viewpoint.

As disclosed in PTLs 1 to 4, when the probe containing the wide variety of additional elements is repeatedly brought into contact with the Sn electrode under high temperature, a large amount of Sn scraped from the electrode adheres to the surface of the electrical contact member, and conductivity of the probe is reduced due to oxidation of the adhered Sn, which may increase the contact resistance. This prevents stable electrical contact from being maintained for a long time.

In another existing technique, the tip of the electrical contact member is formed into an acute shape in order to remove the adhered substance such as Sn originating in the electrode material. However, the effect of preventing the adhesion after repeated contacts at high temperature is not effectively exhibited only through such a technique.

An object of the invention, which has been made in light of the above-described circumstances, is to provide an electrical contact member that achieves low adhesion to a subject (for example, solder, Sn, Al, and Pd), and stably suppresses an increase in contact resistance for a long time, and provide an inspection connection device including the electrical contact member. Specifically, the object of the invention is to provide an electrical contact member that achieves low adhesion to a subject and suppresses an increase in contact resistance even after repeated contacts at a high temperature of about 85° C., and thus maintains stable electrical contact for a long time, and provide an inspection connection device including the electrical contact member.

### Solution to Problem

According to the present invention, the above-described problem is solved by an electrical contact member that is to repeatedly come into contact with a subject, the electrical contact member being summarized in that the surface of the electrical contact member that is to come into contact with the subject is composed of a metallic-element-containing carbon coating containing a metallic element, and the surface roughness Ra1 of the metallic-element-containing carbon coating provided on a slope, where the angle between the slope and the vertical axis of the electrical contact member is 45°, has a value equal to or smaller than a certain value.

In a preferred embodiment of the invention, the Ra1 is 2.7 nm or less.

In another preferred embodiment of the invention, the metallic-element-containing carbon coating has a thickness of 50 to 5000 nm.

In another preferred embodiment of the invention, the metallic element contained in the metallic-element-containing carbon coating is at least one element selected from a group consisting of tungsten, tantalum, molybdenum, niobium, titanium, chromium, palladium, rhodium, platinum, ruthenium, iridium, vanadium, zirconium, hafnium, manganese, iron, cobalt, and nickel.

In another preferred embodiment of the invention, the subject to be inspected contains Sn or Sn alloy.

The invention also includes an inspection connection device having a plurality of electrical contact members each being one of the above-described electrical contact members.

### Advantageous Effects of Invention

For the electrical contact member of the invention, while the metallic-element-containing carbon coating configures the surface of the electrical contact member that is to come into contact with the subject, the metallic-element-containing carbon coating provided on a slope, where the angle between the slope and the vertical axis of the electrical contact member is 45°, has a surface roughness Ra1 having a value equal to or smaller than a certain value. Hence, specifically, low adhesion to a subject is achieved, and an increase in contact resistance is suppressed even after repeated contacts at a high temperature of about 85° C. As a result, stable electrical contact remains for a long time.

### BRIEF DESCRIPTION OF DRAWINGS

FIG. 1 is a fragmentary view illustrating a tip of an electrical contact member and a subject (Sn electrode) in contact with each other.

FIG. 2 is a diagram illustrating a relationship between a slope angle relative to the axis of the electrical contact member and surface roughness Ra1 when the angle is varied within a range from 0 to 90°.

FIG. 3 is a schematic section diagram illustrating a configuration of a tip portion, which is to come into contact with the subject, of the electrical contact member preferably used in the invention.

### DESCRIPTION OF EMBODIMENTS

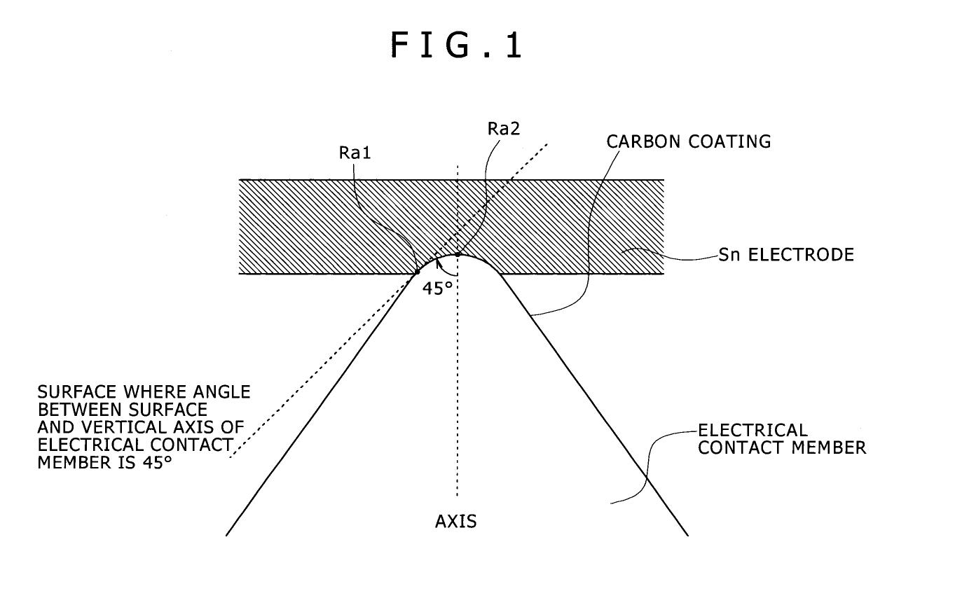

The inventors have made investigations from the viewpoint of providing an electrical contact member that can be used even in a severe condition under high-temperature test environment, while such investigations have been insufficient in existing electrical contact member-related techniques. The inventors have made the investigations mainly on the surface texture of the metallic-element-containing carbon coating configuring the uppermost surface of the electrical contact member. As a result, the inventors have found that the surface roughness Ra1 (see FIG. 1 described later) of the metallic-element-containing carbon coating provided on a slope, where the angle between the slope and the vertical axis of the electrical contact member is 45°, is effectively controlled to be small, i.e., equal to or smaller than a certain value instead of controlling the surface roughness (see Ra2 in Table 2 described later) of the metallic-element-containing carbon coating provided on a surface perpendicular to the axis of the electrical contact member, for example, as in PTL 4, and have finally completed the invention.

Specifically, the electrical contact member of the invention is to repeatedly come into contact with the subject, in which the surface of the electrical contact member that is to come into contact with the subject is composed of a metallic-element-containing carbon coating containing a metallic element. The metallic-element-containing carbon coating is characterized in that the surface roughness Ra1 of the metallic-element-containing carbon coating provided on a slope, where the angle between the slope and the vertical axis of the electrical contact member is 45°, has a value equal to or smaller than a certain value. According to the invention, specifically, it is possible to achieve low adhesion to the subject, and suppress an increase in contact resistance even after repeated contacts at a high temperature of about 85° C.

In this description, “an increase in contact resistance is suppressed even after repeated inspections at high temperature” means that a contact resistance value is 100 mΩ or less after ten thousand contacts to the Sn electrode at 85° C. as described later in embodiments.

In this description, “metallic-element-containing carbon coating” refers to a carbon coating containing at least a metallic element. For example, a metal adhesive layer (Cr, Ni) in FIG. 3 described later is not included in “metallic-element-containing carbon coating” of the invention because the layer does not contain carbon (C) except for inevitably contaminated carbon. In contrast, a mixed layer (Cr+C+W) is included in “metallic-element-containing carbon coating” of the invention because the layer contains carbon (C).

The effect of suppressing Sn adhesion is effectively exhibited by controlling the Ra1 in the sloped region as described above. This is now described with reference to FIG. 1. FIG. 1 is a fragmentary view illustrating a tip of an electrical contact member and a subject (such as a Sn electrode) in contact with each other. As illustrated in FIG. 1, the electrical contact member is brought into contact with the Sn electrode such that the Sn electrode is partially deformed and engaged with the electrical contact member in order to provide certain contact area between the electrical contact member and the Sn electrode. Although the following description is made for convenience on a case where the Sn electrode is used as the subject, the invention is not limited thereto.

The Sn adhesion to the electrical contact member has been previously evaluated with a surface (the region Ra2 in FIG. 1) perpendicular to the axis of the electrical contact member. For example, “surface perpendicular to the axis of the electrical contact member” refers to a portion to be directly in contact with the objective electrode material as the subject (a portion that is to oppositely come into contact with the objective electrode material), such as a keen tip of the electrical contact member.

However, particularly when the objective electrode material is Sn alloy, the Sn alloy is deformed during the contact and also adheres to a slope leading out of the tip of the electrical contact member (i.e., a portion other than, but close to, the surface perpendicular to the axis of the electrical contact member, which is/may be to come into contact with the Sn alloy). As a result of investigations, the inventors have found that the Sn adhesion often starts on a slope (particularly a slope inclined about 45° relative to the axis of the electrical contact member) rather than on the surface perpendicular to the axis. It is further found that as an angle defining the slope increases (i.e., becomes 45° or more), the adhered Sn gradually covers the entire electrical contact member, leading to unstable contact resistance. Although the slope, where the angle between the slope and the vertical axis of the electrical contact member is 45°, exists on the surface of the electrical contact member while surrounding the axis, all positions on the surface should be equally important in the invention.

The inventors have therefore made investigations on a factor affecting the Sn adhesion to the slope from the viewpoint that the Sn adhesion on the slope should be suppressed.

As a result, it has been found that there is a correlation between the Sn adhesion and the surface roughness Ra1 of the metallic-element-containing carbon coating provided on the slope, where the angle between the slope and the vertical axis of the electrical contact member is 45°. It has been further found that the effect of suppressing Sn adhesion is effectively exhibited by controlling the Ra1 to be equal to or smaller than a certain value.

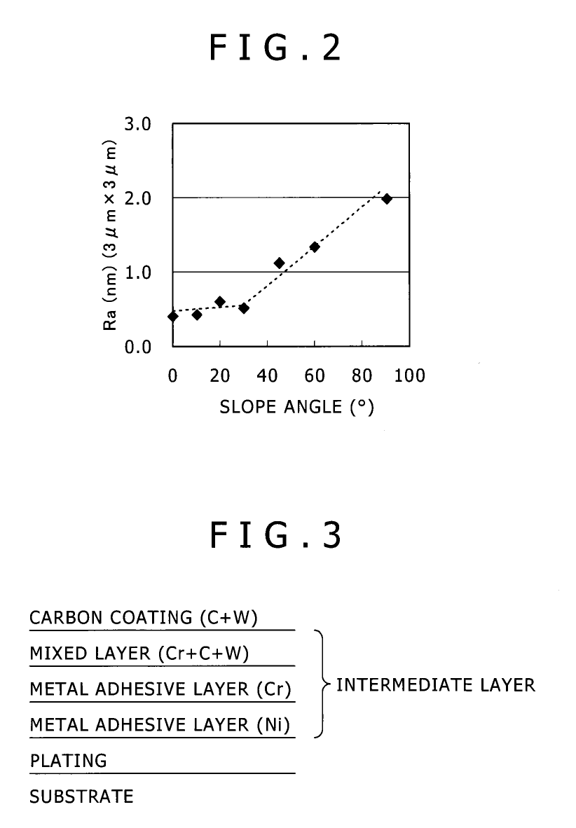

The relationship between the angle and surface roughness of the slope is roughly described as follows. For example, when a carbon coating is formed by a vacuum deposition process such as a sputtering process and CVD, a plasma-facing surface typically has a high-quality and smooth coating thereon, but any other surface is less likely to have a smooth coating thereon. As shown in FIG. 2 and Table 1, the inventors have experimentally found that a carbon coating particularly formed by a sputtering process has a smoothness that is substantially fixed at inclined angles from the opposed surface of roughly 0 to 30° (i.e., slope angles of roughly 90 to 60° relative to the axis of the electrical contact member), but is drastically lowered above the inclined angle of about 30°, resulting in a significant increase in surface roughness.

TABLE 1

| Slope angle | |
|---|---|
| with respect to | |
| opposite surface | Surface roughness Ra1 |
| (°) | (nm) |
| 0 | 0.39 |
| 10 | 0.42 |
| 20 | 0.60 |
| 30 | 0.51 |
| 45 | 1.11 |
| 60 | 1.33 |
| 90 | 1.98 |

FIG. 2 and Table 1 are a graph and a table each illustrating the relationship between the slope angle relative to the axis of the electrical contact member and the surface roughness Ra1 when the slope angle is varied within a range from 0 to 90°. Such a relationship is obtained through the following experiment.

To accurately measure the surface roughness (arithmetic mean roughness: Ra) of the slope, a flat single-crystal silicon substrate is prepared and disposed so as to face each target in order to simulate the surface of a contact probe. Subsequently, the silicon substrate is tilted 0 to 90° and held at the tilted position, and is then covered by the coating.

Specifically, first, 50 nm of Ni and 50 nm of Cr are deposited in this order on the silicon substrate. The detailed sputtering condition is as follows. The space between each target and the silicon substrate is 55 mm.

Ultimate vacuum: 6.6×10⁻⁴ Pa

Target: Ni and Cr

Target size: φ6 in.

Ar gas pressure: 0.18 Pa

Input power density: 8.49 W/cm²

Substrate bias: 0 V

Subsequently, a mixed layer including Cr, W, and carbon is formed 100 nm on the Cr film. Specifically, the mixed layer is formed in such a manner that power is applied to each of the targets (the Cr target and a composite target including a carbon target with a W chip thereon) while being gradually varied to vary a ratio of Cr to carbon containing W.

Subsequently, the carbon coating containing W is formed 400 nm. The detailed sputtering condition is as follows.

Target: Composite target including a carbon target with a W chip thereon

Ar gas pressure: 0.18 Pa

Input power density: 8.49 W/cm²

Substrate bias: −40 V

Target size: φ6 in.

In the invention, surface roughness in the slope region is defined based on such findings, and a value of 45° relative to the axis of the electrical contact member is used as the angle defining the slope.

The function of suppressing Sn adhesion through control of the Ra1 is probably exhibited as follows.

The electrical contact member is inspected as an electronic component by bringing its tip (a top of each projection if the tip has a divided shape) into contact with the Sn electrode as the subject. In such inspection, the electrical contact member is typically brought into contact with the Sn electrode such that the Sn electrode is partially deformed and engaged with the electrical contact member in order to provide certain contact area between the electrical contact member and the Sn electrode (see FIG. 1). In inspection of a large number of electronic components, the electrical contact member is repeatedly brought into contact with the Sn electrode and subjected to current application. This allows the Sn electrode material to gradually adhere to the current application point. Such an adhered material is oxidized and forms an oxide film, so that effective area for contact between the Sn electrode and the electrical contact member is not provided. If such a state remains, the contact resistance value is probably varied.

The Sn electrode material adhered to a portion (a surface perpendicular to the axis of the electrical contact member) near the tip of the electrical contact member is rejected by the geometric effect of the tip of the electrical contact member. If the slope, to which the Sn electrode material tends to adhere, has a low smoothness (large Ra), adhesive power of the Sn electrode material to the slope is large. As a result, the electrode material rejected from the surface perpendicular to the axis of the electrical contact member re-adheres to the slope. The electrical contact member is repeatedly used tens of thousands to hundreds of thousands of times. Hence, even if a slight amount of the electrode material is re-adhered to the slope for each use, incompletely rejected adhered-materials are gradually deposited particularly under a severe use condition such as repeated inspections at high temperature, leading to an increase in amount of the re-adhered material. As a result, the contact resistance is difficult to be stably maintained.

In contrast, when the Ra1 of the slope is designed to be small as in the invention, adhesive power of the Sn electrode material to the slope, to which the Sn electrode material tends to adhere, is small. As a result, the electrode material rejected from the surface perpendicular to the axis of the electrical contact member is readily rejected from the contact portion without re-adhering to the slope. Consequently, a smooth surface is constantly exposed in the contact portion with the Sn electrode, and the contact resistance can be stably maintained.

The Ra1 is controlled to be equal to or smaller than a certain value to allow such a function to be effectively exhibited. If the Ra1 increases, the adhesion amount of Sn increases, leading to an increase in contact resistance after repeated tests at high temperature. For example, as described later in the embodiments, it has been found that when the Ra1 exceeds 2.7 nm, the contact resistance increases after the tests. Consequently, the Ra1 is preferably 2.7 nm or less. The Ra1 is more preferably 2.5 nm or less, and further preferably 2.3 nm or less. Although the lower limit of the Ra1 is not limited from such a viewpoint, a preferred lower limit thereof is roughly 0.3 nm in light of stability at a practical level as with the preferred lower limit of Ra2 described later.

The invention is characterized by such appropriate control of the Ra1, allowing desired characteristics to be effectively exhibited. Furthermore, in the invention, it is preferred that Ra2 in FIG. 1, which has been controlled in the past, is also appropriately controlled in order to allow the characteristics to be further effectively exhibited. The Ra2 is better as it is smaller, and is preferably appropriately controlled in conjunction with the Ra1. Specifically, for example, the Ra2 is preferably controlled to be 1.2 nm or less, and more preferably 0.7 nm or less, depending on the thickness and/or the type of the metallic-element-containing carbon coating as a component of the electrical contact member. The lower limit of the Ra2 is preferably 0.3 nm, for example.

The method of measuring each of the Ra1 and Ra2 is described in detail later in the section of the embodiments.

In the invention, it is preferred that, for example, when a sputtering process is used, one or both of the following operations (a) and (b) is/are appropriately performed in order to produce the above-described surface texture.

(a) Adjusting film-quality control unit for metallic-element-containing carbon coating (specifically, application of bias voltage, reduction in gas pressure, and use of unbalanced magnetron (UBM) as cathode instead of balanced magnetron (BM)).

(b) Reducing thickness of metallic-element-containing carbon coating (described later in detail).

In the operation (a), i.e., adjusting the film-quality control unit for the metallic-element-containing carbon coating, a preferred adjusting method depends on, for example, a sputtering apparatus to be used, and is thus difficult to be uniquely determined. However, for example, when a parallel-plate magnetron sputtering apparatus from SHIMADZU CORPORATION described later is used, a film-quality control unit for the metallic-element-containing carbon coating is preferably controlled as follows.

DC bias voltage: −10 to −200 V, for example.

Reduction in gas pressure: 0.1 to 1 Pa, for example.

Hereinbefore, the surface texture of the uppermost surface portion of the metallic-element-containing carbon coating, by which the invention is most characterized, has been described.

The configuration of the electrical contact member according to the invention is now described more in detail with reference to FIG. 3. FIG. 3 is a diagram showing an example of the tip portion, which is to come into contact with the subject, of the electrical contact member preferably used in the invention, which schematically illustrates a configuration of the tip portion in the embodiments described later. However, the configuration of the tip portion in the invention is not limited thereto. For example, although FIG. 3 shows an intermediate layer having a configuration where metal adhesive layers (including no carbon C) containing different metals (Ni followed by Cr in FIG. 3), and a mixed layer, which contains Cr come from the underlying metal adhesive layer, C come from the carbon coating, and W, are provided in order of closeness to the substrate, the invention is not limited to such a configuration. The composition of each metal adhesive layer or the mixed layer is not limited by the elements in FIG. 3.

In general, the tip portion (generally called plunger) of the electrical contact member, which is to come into contact with the subject, is roughly divided into the carbon coating to be directly in contact with the subject and the substrate in order of closeness to the subject. The intermediate layer may be provided between the carbon coating and the substrate as illustrated in FIG. 3 to enhance adhesion therebetween. A plating layer may be provided on the substrate as illustrated in FIG. 3.

The carbon coating preferably contains at least one element selected from a group consisting of tungsten (W), tantalum (Ta), molybdenum (Mo), niobium (Nb), titanium (Ti), chromium (Cr), palladium (Pd), rhodium (Rh), platinum (Pt), ruthenium (Ru), iridium (Ir), vanadium (V), zirconium (Zr), hafnium (Hf), manganese (Mn), iron (Fe), cobalt (Co), and nickel (Ni). Some of the metallic elements may readily form carbides, and any of such elements is uniformly dispersed in the carbon coating, and stably holds an amorphous and homogenous state. Among them, the platinum group elements of Pd, Rh, Pt, Ru, and Ir is advantageous in that it is less likely to change the contact resistance of the carbon coating, and is relatively uniformly dispersed, resulting in small variations in hardness.

Only one of the metallic elements may be contained, or at least two of them may be contained together. The content of the metal elements in the carbon coating (when only one element is contained, it refers to the content of the one element, and when at least two elements are contained, it refers to the total content) is preferably 2 to 95 atom %, and more preferably 5 to 90 atom %. If the content exceeds such a range, the metal-containing carbon coating loses its specific properties including the amorphous and smooth surface and the hard property, and reliability of semiconductor inspection tends to be lowered. On the other hand, if the content is below the range, the effect of improving conductivity by the added metal is not effectively exhibited.

Among the metal elements, W, Ta, Mo, Nb, Ti, and Cr are preferred, and W is most preferred. The carbide of W is also stable, and W is a metal widely used in the technical field of the invention.

To securely achieve low adhesion with the subject and reduction in contact resistance, the metallic-element-containing carbon coating preferably has a predetermined thickness that is roughly 50 nm to 5 μm (=5000 nm). In general, a carbon coating containing no metallic element has an amorphous and smooth surface. For such a flat surface, even if the carbon coating is increased in thickness, surface roughness is less likely to be increased. Through the results of investigation, however, the inventors have found that an increase in thickness of the metallic-element-containing carbon coating reduces smoothness of the slope, leading to an increase in the Ra1 defined in the invention. The metallic-element-containing carbon coating preferably has a predetermined thickness in light of strength and durability. On the other hand, since the carbon coating has a resistance higher than metal, large thickness of the carbon coating leads to an increase in contact resistance of the electrical contact member. Consequently, the preferred thickness of the metallic-element-containing carbon coating is defined to be within the above-described range based on such findings. The thickness of the metallic-element-containing carbon coating is more preferably 200 nm to 2 μm.

To describe again, the invention is characterized by controlling the surface texture (Ra1 and preferably Ra2) of the metallic-element-containing carbon coating. Other configurations are not particularly limited, and any configuration typically used in the technical field of the electrical contact member can be appropriately selectively used.

For example, the preferred carbon coating of the invention has high hardness, good wear resistance, and good slidability, and is amorphous over the entire surface of the carbon coating, as typified by the diamond like carbon (DLC) film. This is because such a carbon coating is not consumed even after repeated contacts with the objective material, and is free from adhesion of the objective material, and is less likely to increase a level of surface irregularities due to the amorphous property.

The metallic-element-containing carbon coating (preferably including the metal adhesive layer containing no carbon as illustrated in FIG. 3) as a component of the electrical contact member according to the invention can be formed by any of various film formation processes such as a chemical vapor deposition (CVD) process, a sputtering process, and an arc ion plating (AIP) process. However, the sputtering process or the AIP process is preferably used because it allows easy formation of a carbon coating having low electric resistance, or allows a metallic element to be readily introduced into the carbon coating.

In particular, the sputtering process is most preferred because it allows formation of a high-quality carbon coating. While the carbon coating basically has a diamond structure or a graphite structure, the carbon coating desirably has an amorphous structure, which is an intermediate structure between the two, in order to achieve adequate hardness and low electrical conduction. Such a structure is most easily produced by the sputtering process, and is substantially free from contamination of hydrogen that interferes with electrical conduction.

The substrate disposed below the carbon coating preferably includes beryllium copper (Be—Cu); palladium (Pd), tungsten (W), iridium (Ir), or alloy thereof; and carbon tool steel in light of strength and conductivity. Plating such as Au-based plating may be provided on the substrate (between the carbon coating and the substrate) as necessary.

An intermediate layer for improving adhesion is preferably provided between the substrate or the plating thereon (hereinafter referred to as “substrate etc.”) and the carbon coating. This is because adhesion between the substrate etc. and the carbon coating is basically low, and the carbon coating is easily separated from the substrate etc. at the interface therebetween because compressive stress occurs during formation of the carbon coating due to a difference in thermal expansion coefficient between the carbon coating and a metal configuring the substrate etc. A known intermediate layer may be used as such an intermediate layer. For example, an intermediate layer described in Japanese Unexamined Patent Application Publication No. 2002-318247 can be referred. Specific examples of the intermediate layer include an intermediate layer having at least one metal adhesive layer including a metal (for example, Ni) having good adhesion to the substrate or an alloy thereof; and an intermediate layer including the metal adhesive layer and a mixed layer provided thereon, the mixed layer containing the metal (for example, Ni) of the metal adhesive layer, the metallic element (for example, Pd) contained in the carbon coating, and carbon. The mixed layer may be a gradient layer in which the carbon content therein continuously increases from a substrate side to a carbon coating side. While an appropriate metal may be selectively used for the metal adhesive layer depending on types of the substrate etc., Ni is preferably used when the substrate etc. (particularly the plating) includes Au. In this way, an appropriate intermediate layer is provided depending on the substrate etc., and thereby good durability is achieved.

For example, in the embodiments described later, as illustrated in FIG. 3, a mixed layer (Cr+C+Pd) is provided on the metal adhesive layer (Cr), and concentration of each element in the mixed layer is adjusted to be gradually varied. Stress in the mixed layer is also gradually varied through formation of such a mixed layer, thereby making it possible to effectively prevent separation of the mixed layer from the substrate. In addition, since Cr and Pd are contained in the mixed layer, conductivity of the mixed layer is also improved.

While a typical form of the electrical contact member of the invention includes a contact probe pin, other forms such as a flat spring are also included. Some of such forms has a portion corresponding to a corner (for example, a corner of a sheet spring and a projection of a semispherical shape), at which shearing force as described above may be generated. For the contact probe pin, there are known various shapes of its contact portion, which is to come into contact with the subject. For example, there are contact portions divided into two, three, and four (and a contact portion being not divided), all of which are included in the electrical contact member of the invention.

Solder is typically used as the subject (electrode) to be inspected with the electrical contact member of the invention. Solder essentially contains Sn that particularly easily adheres to the surface of the contact probe pin. Hence, when the subject is composed of Sn or Sn alloy, the effect of the electrical contact member of the invention is particularly effectively exhibited.

As described in detail hereinbefore, according to the invention, there is provided the electrical contact member such as the contact probe used to inspect electrical properties of a semiconductor element, the tip of the contact probe being to be repeatedly brought into contact with the subject such as the electrode. In particular, according to the invention, there is provided the electrical contact member having good durability so that its conductivity is not reduced even after repeated inspections at high temperature.

The invention also includes an inspection connection device including the electrical contact member. Examples of the inspection connection device include an inspection socket, a probe card, and an inspection unit.

Although the invention is now described in detail with embodiments, the invention should not be limited thereto, and modifications or alterations thereof may be made within the scope without departing from the gist described before and later, all of which are included in the technical scope of the invention.

### Embodiments

### First Embodiment

In the first embodiment, as listed in Table 2, various samples Nos. 1 to 4 were prepared, and each sample was measured in Ra1 and Ra2 and in contact resistance after the high-temperature test.

In the first embodiment, two types of contact probes A and B were used as described below. In detail, as shown in Table 2, the contact probes A and B were used for Nos. 1 and 4, while only the contact probe A was used for Nos. 2 and 3.

(A) Spring-incorporating probe having four-divided tip (YPW-6XT03-047 from YOKOWO CO., LTD.), in which the uppermost surface of a Be—Cu substrate is coated with Au—Co alloy. It is listed as “crown” in Table 2.

(B) Contact probe having one end apex (YPW-6XA03-062 from YOKOWO CO., LTD., specifications of plating and the like are the same as those in (A)). It is listed as “pencil” in Table 2.

Subsequently, the intermediate layer (the metal adhesive layers and the mixed layer in FIG. 3) for improving adhesion to the substrate, and the carbon coating were sequentially formed by a sputtering process in the following manner.

### (No. 1)

No. 1 has a layer configuration including the metal adhesive layers (Ni, Cr), the mixed layer (Cr+C+W), and the carbon coating (C+W) in order of closeness to the substrate as illustrated in FIG. 3. No. 1 was formed with a magnetron sputtering apparatus from SHIMADZU CORPORATION, of which the cathode was partially changed into an unbalanced magnetron (UBM) producing an unbalanced magnetic field for the cathode. Since UBM increases plasma density near the substrate, a plasma region is expanded up to near a sample, leading to formation of a coating having higher quality.

Specifically, a carbon (graphite) target, a chromium target, and a nickel target were disposed in the magnetron sputtering apparatus, and the contact probe A or B was set therein so as to face each target. Each contact probe was disposed such that a portion, which was to face the electrode in use, faced the target, and any region other than an area about 0.3 mm around a portion, which was to come into contact with the electrode, was masked by a jig to allow the metallic-element-containing carbon coating to adhere only to the region.

A flat single-crystal silicon substrate was prepared and disposed so as to face each target to simulate the surface of the contact probe in order to accurately measure the Ra1 of the slope (defining 45° with the axis of the contact probe). The silicon substrate was then tilted 45° and held at the tilted position, and then coated with the coating. The first embodiment employed the silicon substrate for the following two reasons.

(a) Influence of irregularities of the substrate surface or the underlying plating surface should be eliminated because the surface roughness Ra of the contact probe tends to be affected by film quality of the metallic-element-containing carbon coating.

(b) Technical difficulties should be reduced during measurement by an atomic force microscope (AFM, which is used to measure Ra1 and Ra2 as described later).

The space between each target and the contact probe and the space between each target and the silicon substrate were each 55 nm.

Specifically, first, 50 nm of Ni and 50 nm of Cr were deposited in this order on the Au-based plating. The detailed sputtering condition was as follows.

Ultimate vacuum: 6.7×10⁻⁴ Pa

Target: Ni and Cr

Target size: φ6 in.

Ar gas pressure: 0.18 Pa (as shown in Table 2)

Input power density: 8.49 W/cm²

Substrate bias: 0 V

Subsequently, a mixed layer including Cr and carbon containing W was formed 500 nm thick on the Cr film. Specifically, the mixed layer was formed in such a manner that power was applied to each of the targets (the Cr target and a composite target including a carbon target with a W chip thereon) while being gradually varied to vary a ratio of Cr to carbon containing W. In this way, the mixed layer (Cr+C+W), in which concentration of each element is gradually varied, is provided between the metal adhesive layer (Cr) and the carbon coating, and thereby stress in the mixed layer is also gradually varied, so that separation of the mixed layer from the substrate can be effectively prevented.

Subsequently, the carbon coating containing W was formed in a thickness of 400 nm (the thickness of the metallic-element-containing carbon coating (the mixed layer and the carbon coating containing W) in No. 1 was 900 nm in total, see Table 2). The detailed sputtering condition was as follows. The carbon coating containing W was generally formed while a DC-bias voltage was applied as described below.

Target: Composite target including a carbon target with a W chip thereon

Ar gas pressure: 0.18 Pa (as shown in Table 2)

Input power density: 8.49 W/cm²

Substrate bias: −40 V

Target size: φ6 in.

### (No. 2)

As with No. 1, No. 2 has a layer configuration including the metal adhesive layers (Ni, Cr), the mixed layer (Cr+C+W), and the carbon coating (C+W) in order of closeness to the substrate. No. 2 was prepared by a process substantially similar to that for No. 1. No. 2 is different from No. 1 in that Ar gas pressure was 0.33 Pa (as shown in Table 2), and the substrate bias was 0 V (no bias voltage was applied) during formation of the carbon coating containing W.

### (No. 3)

As with Nos. 1 and 2, No. 3 has a layer configuration including the metal adhesive layers (Ni, Cr), the mixed layer (Cr+C+W), and the carbon coating (C+W) in order of closeness to the substrate. No. 3 is different from No. 2 in that the metallic-element-containing carbon coating (the mixed layer and the carbon coating containing W) was formed while deposition time was varied such that the thickness of the carbon coating was 1500 nm in total (see Table 2).

### (No. 4)

No. 4 has a layer configuration including the metal adhesive layer (Cr), the mixed layer (Cr+C+W), and the carbon coating (C+W) in order of closeness to the substrate. No. 4 employed a balanced magnetron (BM) cathode unlike the Nos. 1 to 3.

Specifically, the Cr layer was formed 50 nm thick by a magnetron sputtering apparatus from SHIMADZU CORPORATION. The detailed sputtering condition was as follows.

Ultimate vacuum: 6.7×10⁻⁴ Pa

Target: Cr

Target size: φ6 in.

Ar gas pressure: 0.39 Pa (as shown in Table 2)

Input power density: 5.66 W/cm²

Substrate bias: 0 V

Subsequently, a mixed layer including Cr and carbon containing W was formed 100 nm thick on the Cr film. Specifically, the mixed layer was formed in such a manner that power was applied to each of the targets (the Cr target and a composite target including a carbon target with a W chip thereon) while being adjusted to vary a ratio of Cr to carbon containing W. In this way, the mixed layer (Cr+C+W), in which concentration of each element is gradually varied, is provided between the metal adhesive layer (Cr) and the carbon coating, and thereby stress in the mixed layer is also gradually varied, so that separation of the mixed layer from the substrate can be effectively prevented.

Subsequently, the carbon coating containing W was formed 800 nm. The detailed sputtering condition was as follows.

Target: Composite target including a carbon target with a W chip thereon

Ar gas pressure: 0.39 Pa (as shown in Table 2)

Input power density: 5.66 W/cm²

Substrate bias: 0 V

Target size: φ6 in.

### (Measurement of Surface Texture Ra)

In the first embodiment, Ra1 and Ra2 were measured by an atomic force microscope (AFM). AFM enables detection of fine irregularities that have been failed to be detected by a laser microscope.

Specifically, Ra1 and Ra2 were measured as follows.

Meter: Scanning Probe Microscope from Digital Instruments

Observation mode: Tapping mode AFM

Measuring range: 3×3 μm

Measuring atmosphere: Air

(Measurement of Contact Resistance after Repeated Contacts at High Temperature)

Each of the samples produced in the above manner was brought into contact with the Sn electrode (including Cu alloy coated with Sn about 10 μm) for current application ten thousand times, and a value of contact resistance caused by Sn adhesion to the tip of the contact probe was measured. The measurement was performed by the following method. Specifically, two first wirings were connected to the Sn electrode, and two second wirings were also connected to an Au electrode that was to come into contact with an opposite side of the contact probe. A current was applied to each of one first wiring and one second wiring, and a voltage between the other first wiring and the other second wiring was measured. That is, the total of resistance of the contact probe itself, total contact resistance with respect to the upper and lower electrodes, and total internal resistance of the upper and lower electrodes were measured using what is called Kelvin connection, while other resistance components were cancelled.

Specifically, a current of 100 mA was applied at a frequency of once every 100 contacts up to 10,000 contacts at 85° C., while contact resistance was measured based on the voltage generated at such current application. In detail, the contact resistance values at first contact, at 101th contact, . . . , and at 10001th contact were measured. Similar operation was repeated twice (n=2), and a sample in which both the contact resistance values were 100 mΩ or less was determined to be ∘, and a sample in which at least one of the contact resistance values exceeded 100 mΩ was determined to be ×.

Table 2 collectively shows the results.

TABLE 2

| | Thickness of | | | | | | | | |
|---|---|---|---|---|---|---|---|---|---|
| | metallic-element- | Thickness | | Gas | | Surface roughness Ra | | Contact resistance value | |
| | containing carbon | of adhesive | | pressure | DC- | (nm) | | after high-temperature test | |
| No. | coating (nm) | layer (nm) | Cathode | (Pa) | bias | Ra 2 | Ra 1 | Crown | Pencil |
| 1 | 900 | 100 | UBM | 0.18 | Applied | 0.33 | 1.74 | ∘ | ∘ |
| 2 | 900 | 100 | UBM | 0.33 | Not applied | 0.64 | 2.23 | ∘ | |
| 3 | 1500 | 100 | UBM | 0.33 | Not applied | 0.74 | 3.32 | x | |
| 4 | 900 | 50 | BM | 0.39 | Not applied | 1.94 | 2.84 | x | x |

Table 2 suggests the following findings.

In Nos. 1 and 2, Ra1 (at an inclined angle 45°) was controlled to be small, i.e., 1.74 nm and 2.23 nm, respectively; hence, low contact resistance remained even after the high-temperature test.

On the other hand, in No. 3, Ra1 (at an inclined angle 45°) was large, 3.32 nm, compared with No. 1 or 2, and the contact resistance after the high-temperature test was high. This is probably due to a composite effect of the followings. That is, compared with No. 1, No. 3 was large in thickness of the metallic-element-containing carbon coating, was high in gas pressure during formation of the metallic-element-containing carbon coating, and was subjected to no bias voltage application.

In No. 2, no bias voltage was applied, and gas pressure was high as with No. 3. However, since the thickness of the metallic-element-containing carbon coating was small as with No. 1, good properties were probably exhibited.

In No. 4, Ra1 (with an inclined angle 45°) was large, 2.84 nm, compared with No. 2, and the contact resistance after the high-temperature test was also high. This is probably due to a composite effect of the followings. That is, although No. 4 was the same in thickness of the metallic-element-containing carbon coating compared with No. 2, No. 4 was slightly high in gas pressure during formation of the metallic-element-containing carbon coating, was not provided with the UBM cathode, and was subjected to no bias voltage application. In No. 4, the adhesive layer had a thickness of 50 nm, which was smaller than the thickness (100 nm) of the adhesive layer of each of Nos. 1 to 3. Through experimental results, the inventors have found that when the adhesive layer has a thickness within a range from 50 to 100 nm, Ra1 is substantially not varied, i.e., Ra1 is substantially not affected by the thickness (not shown in Tables).

Such results show that Ra1 is effectively controlled to be roughly 2.7 nm or less under the condition of the first embodiment. Furthermore, appropriately controlling at least one of the thickness of the metallic-element-containing carbon coating, usage of the UBM cathode, and application of the bias voltage was found to be effective in adjusting Ra1.

Furthermore, the results on Nos. 3 and 4 showed that not only reduction in Ra2 but also reduction in Ra1 was indispensable to allow the desired properties to be exhibited.

### Second Embodiment

In the second embodiment, there was investigated influence on Ra1 (and Ra2) of the way of applying the bias voltage during formation of the carbon coating excluding the mixed layer (specifically the carbon coating containing W).

Specifically, No. 5 in Table 3 is a modification of the No. 1 in Table 2, in which the carbon coating containing W has a thickness varied from that in No. 1 for DC-bias application during formation of the carbon coating. The details are as follows.

No. 1: Bias voltage (−40V) was continuously applied from start of formation of the carbon coating containing W up to the thickness thereof of 400 nm. Consequently, the thickness of the carbon coating for bias voltage application was 400 nm as shown in Table 3.

No. 5: Although the thickness of the carbon coating containing W was 400 nm as with No. 1, the bias voltage was not applied until the thickness of the carbon coating reached 360 mm. Subsequently, 40 nm of the carbon coating was formed while the bias voltage was applied.

Consequently, the thickness of the carbon coating for bias voltage application was 40 nm as shown in Table 3.

Subsequently, No. 5 in Table 3 was examined in the surface roughness (Ra1 and Ra2) and the contact resistance value after the high-temperature test as with No. 1. No. 5 was subjected to the experiments using only the contact probe (A) (crown type).

Table 3 shows the results of such experiments. Table 3 further shows the results of the No. 1 in Table 2 for reference.

TABLE 3

| | Thickness of | | | | Thickness of carbon | Surface | | | |
|---|---|---|---|---|---|---|---|---|---|
| | metallic-element- | Thickness | | Gas | coating containing | roughness Ra | | Contact resistance value | |
| | containing carbon | of adhesive | | pressure | W for application of | (nm) | | after high-temperature test | |
| No. | coating (nm) | layer (nm) | Cathode | (Pa) | DC-bias (nm) | Ra 2 | Ra 1 | Crown | Pencil |
| 1 | 900 | 100 | UBM | 0.18 | 0 | 0.33 | 1.74 | ∘ | ∘ |
| 5 | 900 | 100 | UBM | 0.18 | 0 | 0.59 | 1.87 | ∘ | |

As shown in Table 3, when the thickness of the carbon coating formed with application of the bias voltage was changed from 400 nm (No. 1) to 40 nm (No. 5), Ra1 was increased from 1.74 nm (No. 1) to 1.87 nm (No. 5). However, since such an increased thickness was also within the preferred value range defined in the invention, low contact resistance remained even after the high-temperature test.

Such experimental results showed that Ra1 was also appropriately adjusted by varying the way of applying the bias voltage.

The embodiments disclosed herein should be regarded to be exemplary and not limitative in all respects. The scope of the invention is defined by claims rather than the description, and is intended to include all modifications and alterations in the sense equivalent to or within the scope of claims. The present application is based on Japanese patent application (JP-2012-274117) filed on Dec. 14, 2012, the content of which is hereby incorporated by reference.

1. An electrical contact member that is to repeatedly come into contact with a subject, wherein
a surface of the electrical contact member that is to come into contact with the subject comprises a metallic-element-containing carbon coating containing a metallic element, and
surface roughness Ra1 of the metallic-element-containing carbon coating provided on a slope, where the angle between the slope and the vertical axis of the electrical contact member is 45°, has a value equal to or smaller than a certain value.

2. The electrical contact member according to claim 1, wherein the Ra1 is 2.7 nm or less.

3. The electrical contact member according to claim 1, wherein the metallic-element-containing carbon coating has a thickness of 50 to 5000 nm.

4. The electrical contact member according to claim 1, wherein the metallic element contained in the metallic-element-containing carbon coating is at least one element selected from a group consisting of tungsten, tantalum, molybdenum, niobium, titanium, chromium, palladium, rhodium, platinum, ruthenium, iridium, vanadium, zirconium, hafnium, manganese, iron, cobalt, and nickel.

5. The electrical contact member according to claim 1, wherein the subject comprises Sn or Sn alloy.

6. An inspection connection device, comprising a plurality of electrical contact members each being the electrical contact member according to claim 1.

7. The electrical contact member according to claim 2, wherein the metallic-element-containing carbon coating has a thickness of 50 to 5000 nm.

8. The electrical contact member according to claim 2, wherein the metallic element contained in the metallic-element-containing carbon coating is at least one element selected from a group consisting of tungsten, tantalum, molybdenum, niobium, titanium, chromium, palladium, rhodium, platinum, ruthenium, iridium, vanadium, zirconium, hafnium, manganese, iron, cobalt, and nickel.

9. The electrical contact member according to claim 2, wherein the subject comprises Sn or Sn alloy.

10. An inspection connection device, comprising a plurality of electrical contact members each being the electrical contact member according to claim 2.
